(19) United States
(12) Patent Application Publication
(10) Pub. No.: US 2006/0275954 A1
(43) Pub. Date: Dec. 7, 2006

(54) Method for removing a cover from a semiconductor wafer

(75) Inventor: Donna Yoshie Sison, Vancouver, WA (US)

Correspondence Address: TriQuint Semiconductor, Inc., 2300 NE Brookwood Parkway, Hillsboro, OR, 97124, US

(73) Assignee: TriQuint Semiconductor, Inc.

(21) Appl. No.: 11/146,832

(22) Filed: Jun. 6, 2005

(51) Int. Cl. H01L 21/00

(52) U.S. Cl. 438/125

(57) ABSTRACT

A method of removing a cover from a wafer. A wafer, which includes a cover, is put on a support structure. The wafer is flexed to separate a portion of the wafer from the cover, and an impact force is applied to remove the cover from the wafer.

### TECHNICAL FIELD

Embodiments of the invention are generally related to the field of semiconductor processing, and, in particular, to removing a cover from a semiconductor wafer.

### BACKGROUND

In the manufacture of microelectronic components, such as, but not limited to, a power amplifier, a low-noise amplifier or a switch, multiple components can be created on a semiconductor substrate. One example of a microelectronic component is a semiconductor component or an integrated circuit. A microelectronic component created on a substrate is commonly referred to as a die. The top of the substrate is commonly referred to as the “front side,” and the bottom is commonly referred to as the “backside”.

After die are created on the front side, the substrate is processed on the backside, for example, the substrate may be thinned. For backside processing, a protective cover, commonly referred to as a carrier, is typically placed over the die. Adhesive is typically applied between the bottom of the carrier and the tops of the die, so that the carrier remains fixed to the tops of the die. A substrate that contains die is commonly referred to as a semiconductor wafer, or simply a wafer.

Once backside processing is complete, the carrier is removed from the wafer so that further processing can take place. For example, after the carrier is removed, the next process might be dicing the wafer to separate the die into individual pieces. One way to remove the carrier from the wafer is to place the wafer including the carrier in a chemical bath. The chemical breaks down the adhesive bond between the carrier and the die. However, using a chemical bath is time consuming, taking hours or even days to break the adhesive bond.

Designing holes in the carrier can accelerate the chemical-bath process, because the holes expose more of the surface area of the adhesive bond to the chemical. However, even with holes, the time to remove the carrier is still substantial, and the chemical can damage the die. In addition, the holes can affect the carrier's ability to protect the die. For example, in areas surrounding the holes, wafer thickness and surface finish may be affected.

Another way to remove the carrier is to place the wafer including the carrier on a heated surface. The heat breaks down the adhesive bond between the carrier and the die. However, using a heated surface to remove the carrier can also be time consuming. In addition, depending on the surface tension of the melted adhesive between the carrier and die, the die can be mechanically damaged as the carrier is removed.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a flow chart illustrating one embodiment of a method of removing a cover from a semiconductor wafer.

FIG. 2 illustrates a cross-section of removing a carrier from a wafer in accordance with one embodiment of the invention.

### DETAILED DESCRIPTION

A method of removing a protective cover from a semiconductor wafer is described. In the following description, for purposes of explanation, numerous specific details are set forth. It will be apparent, however, to one skilled in the art that embodiments of the invention can be practiced without these specific details. In other instances, structures and devices are shown in block diagram form in order to avoid obscuring the understanding of this description.

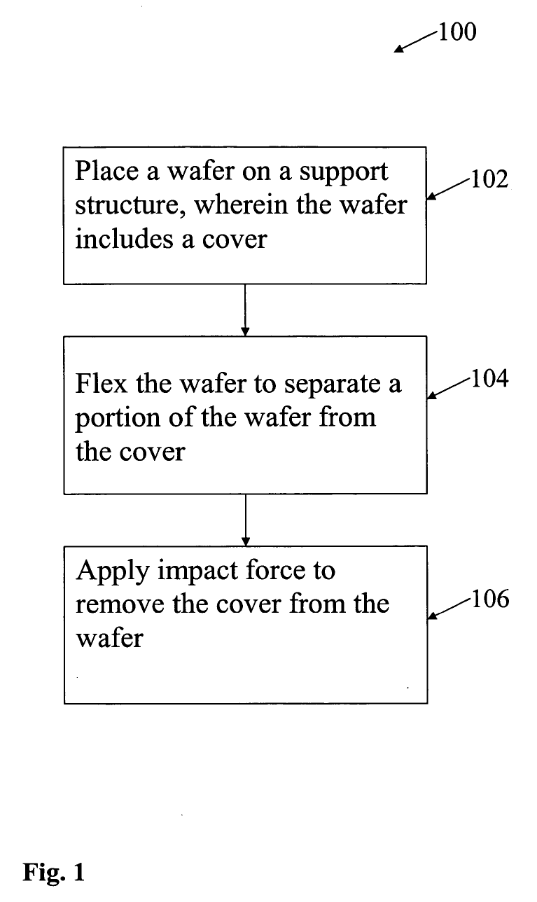

FIG. 1 is a flow chart illustrating one embodiment of a method of removing a cover from a semiconductor wafer. At 102 of method 100, a wafer is placed on a support structure, wherein the wafer includes a cover, for example, a carrier. Embodiments of the invention are described in terms of a wafer that includes semiconductor die. However, embodiments of the invention may be practiced with a bare wafer that does not include semiconductor die or any other components or elements, or a wafer that includes components or elements other than semiconductor die. As used herein, “wafer” includes both a bare wafer and a wafer that includes semiconductor die or other elements or components. In one embodiment, the support structure is a film frame, or wafer saw frame. In another embodiment, the support structure is a vacuum chuck. A film frame, a wafer saw frame and a vacuum chuck are known to those of ordinary skill in the art and therefore will not be described in detail herein.

At 104, the wafer on the support structure is flexed to separate a portion of the wafer from the cover. In one embodiment, the wafer is flexed using a pressure differential to pull down a portion of the wafer, for example, applying a vacuum to the backside of the wafer, thereby flexing the wafer downward. In another embodiment, the wafer is flexed by applying a force to push up a portion of the wafer, for example, using air, gas, an object, water or other fluid to push up a portion of the backside of the wafer, thereby flexing a portion of the wafer upward. Flexing the wafer breaks the bond between the bottom of the cover and the top of one or more semiconductor die (or other elements or components on the wafer), if the wafer contains semiconductor die or other elements or components. However, if the wafer is bare, flexing the wafer breaks the bond between the bottom of the cover and the top of the wafer. Although embodiments of the invention are described in terms of flexing the wafer to separate a portion of the wafer from the cover, embodiments of the invention may be practiced by flexing the cover to separate a portion of the wafer from the cover.

At 106, an impact force is applied. The impact force may be applied to the wafer, or the cover, or both, for example, at the junction between the wafer and the cover, to remove the cover from the wafer, or remove the wafer from the cover. As used herein, removing the cover from the wafer also includes removing the wafer from the cover. In one embodiment, the impact force comprises air injected between the wafer and the cover. In another embodiment, the impact force comprises an object, for example, a rod or lever, inserted between the wafer and the cover. In another embodiment, the impact force is a cleaving force applied to the cover. Although embodiments of the invention are described in terms of applying an impact force, embodiments of the invention may be practiced without applying the impact force, in that the cover is removed from the wafer when the wafer (or the cover) is flexed at 104.

Consequently, a cover is removed from a wafer without the use of a chemical bath or heat, although method 100 can be used in conjunction with a chemical bath and/or heat and/or other techniques. Using method 100, alone or in conjunction with one or more other techniques, the amount of time needed to remove a cover from a wafer can be reduced, as can the possibility of damaging die due to the technique used to remove the cover.

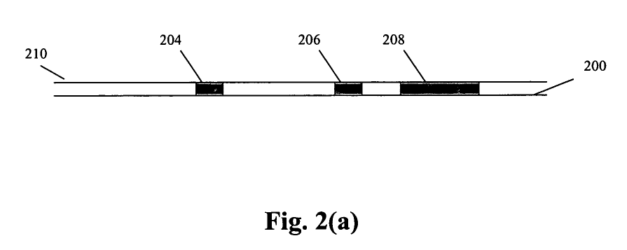

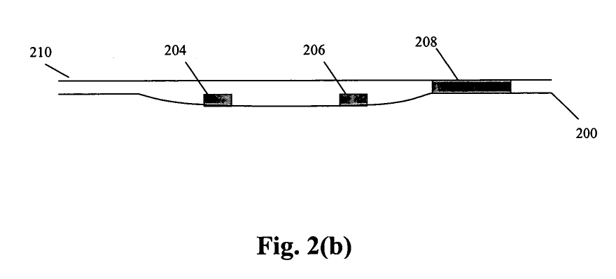

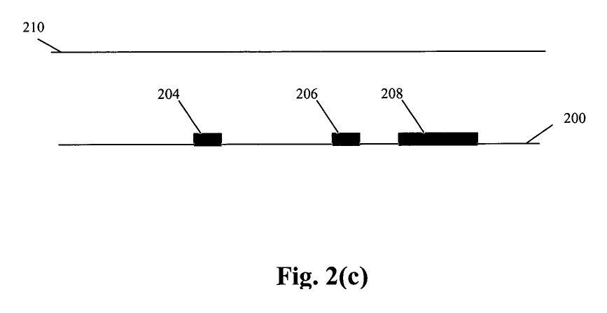

FIG. 2 illustrates a cross-section of removing a carrier from a wafer in accordance with one embodiment of the invention. In FIG. 2(a), wafer 200 has been placed on a support structure (not shown). Wafer 200 includes die 204, 206 and 208, for example. In addition, carrier 210 covers wafer 200, for example, adhesive has been applied to the bottom of the carrier and/or the tops of one or more of the die. For purposes of illustration, wafer 200 is shown with three die. However, wafer 200 may include any number of die. Embodiments of the invention are not affected by the number of die, if any, on wafer 200.

In FIG. 2(b), wafer 200 is flexed, for example, a vacuum is applied to wafer 200 to pull down a portion of wafer 200. This causes the tops of one or more of die 204, 206 and 208 to be separated from the bottom of carrier 210. To remove carrier 210 from wafer 200 (or vice versa) as shown in FIG. 2(c), an impact force (not shown) is applied is applied to carrier 210 or wafer 200 or both.

Reference in the foregoing specification to “one embodiment” or “an embodiment” means that a particular feature, structure, or characteristic described in connection with the embodiment is included in at least one embodiment of the invention. The appearances of the phrase, “in one embodiment” in various places in the specification are not necessarily all referring to the same embodiment.

In the foregoing specification, the invention has been described with reference to specific embodiments thereof. It will, however, be evident that various modifications and changes can be made thereto without departing from the broader spirit and scope of the invention. The specification and drawings are, accordingly, to be regarded in an illustrative rather than a restrictive sense.

What is claimed is:

1. A method, comprising:
putting a wafer on a support structure, wherein the wafer includes a cover;
flexing the wafer to separate a portion of the wafer from the cover; and
applying an impact force to remove the cover from the wafer.

2. The method of claim 1, wherein putting the wafer on the support structure comprises putting the wafer on a saw frame.

3. The method of claim 1, wherein putting the wafer on the support structure comprises putting the wafer on a vacuum chuck.

4. The method of claim 1, wherein flexing the wafer to separate the portion of the wafer from the cover comprises applying a force to flex the wafer.

5. The method of claim 4, wherein applying the force to flex the wafer comprises applying air to the backside of the wafer to push up a portion of the backside of the wafer.

6. The method of claim 4, wherein applying the force to flex the wafer comprises applying a vacuum to the backside of the wafer to pull down a portion of backside of the wafer.

7. The method of claim 1, wherein flexing the wafer to separate the portion of the wafer from the cover comprises flexing the wafer to separate a bottom of the cover from a top of a component on the wafer.

8. The method of claim 7, wherein flexing the wafer to separate the bottom of the cover from the top of the component on the wafer comprises flexing the wafer to separate the bottom of the cover from the top of a semiconductor die on the wafer.

9. The method of claim 1, wherein flexing the wafer to separate the portion of the wafer from the cover comprises flexing the wafer to separate a bottom of the cover from a top of the wafer.

10. The method of claim 1, wherein applying the impact force to remove the cover from the wafer comprises applying the impact force between the cover and the wafer.

11. The method of claim 10, wherein applying the impact force between the cover and the wafer comprises applying air between the cover and the wafer.

12. The method of claim 10, wherein applying the impact force between the cover and the wafer comprises inserting an object between the cover and the wafer.

13. The method of claim 1, wherein applying the impact force to remove the cover from the wafer comprises applying the impact force to the wafer.

14. The method of claim 1, wherein applying the impact force to remove the cover from the wafer comprises applying the impact force to the cover.

15. The method of claim 14, wherein applying the impact force to the cover comprises applying a cleaving force to the cover.

16. A method, comprising:
putting a wafer on a support structure, wherein the wafer includes a cover; and
flexing the wafer to remove the wafer from the cover.

17. The method of claim 16, wherein flexing the wafer comprises applying a force to flex the wafer.

18. The method of claim 17, wherein applying the force to flex the wafer comprises applying the force to the backside of the wafer to push up a portion of the backside of the wafer.

19. The method of claim 17, wherein applying the force to flex the wafer applying a vacuum to the backside of the wafer to pull down a portion of the backside of the wafer.
